(19) United States
(12) Patent Application Publication
(10) Pub. No.: US 2024/0206070 A1
(43) Pub. Date: Jun. 20, 2024

(54) DISPLAY DEVICE

(71) Applicant: Industrial Technology Research Institute, Hsinchu (TW)

(72) Inventors: Wan-Yi Lin, Miaoli County (TW); Ming-Hsien Wu, Hsinchu County (TW)

(73) Assignee: Industrial Technology Research Institute, Hsinchu (TW)

(21) Appl. No.: 18/090,459

(22) Filed: Dec. 28, 2022

(30) Foreign Application Priority Data
Dec. 16, 2022 (TW) 111148435

(51) Int. Cl. H05K 1/14; H05K 1/18

(52) U.S. Cl. CPC H05K 1/147; H05K 1/18; H05K 2201/10128

(57) ABSTRACT

A display device includes a first display module. The first display module includes a first support substrate, a first flexible substrate, a first conductive circuit, a plurality of first electronic elements, and a protection layer. The first flexible substrate is disposed on the first support substrate. The first conductive circuit is disposed on the first support substrate. The first electronic elements are disposed on the first conductive circuit, where the first conductive circuit is located between the first electronic elements and the first support substrate and is electrically connected to the first electronic elements. The protection layer covers the first electronic elements and the first conductive circuit. The first flexible substrate and the first conductive circuit are bent from a side surface of the first support substrate to a back surface of the first support substrate.

### CROSS-REFERENCE TO RELATED APPLICATION

This application claims the priority benefit of Taiwanese application no. 111148435, filed on Dec. 16, 2022. The entirety of the above-mentioned patent application is hereby incorporated by reference herein and made a part of this specification.

### TECHNICAL FIELD

The disclosure relates to a display device.

### BACKGROUND

In recent years, there has been an increasing demand for large-size, curved, and/or specially-shaped displays. However, in consideration of yield, costs, and/or other factors, it is difficult to satisfy the above requirements on one single panel.

### SUMMARY

A display device which is conductive to accomplishment of size-free splicing is introduced herein.

An embodiment of the disclosure provides a display device that includes a first display module. The first display module includes a first support substrate, a first flexible substrate, a first conductive circuit, a plurality of first electronic elements, and a protection layer. The first flexible substrate is disposed on the first support substrate. The first conductive circuit is disposed on the first support substrate. The first electronic elements are disposed on the first conductive circuit, where the first conductive circuit is located between the first electronic elements and the first support substrate and is electrically connected to the first electronic elements. The protection layer covers the first electronic elements and the first conductive circuit. The first flexible substrate and the first conductive circuit are bent from a side surface of the first support substrate to a back surface of the first support substrate.

Several exemplary embodiments accompanied with figures are described in detail below to further describe the disclosure in details.

### BRIEF DESCRIPTION OF THE DRAWINGS

The accompanying drawings are included to provide a further understanding, and are incorporated in and constitute a part of this specification. The drawings illustrate exemplary embodiments and, together with the description, serve to explain the principles of the disclosure.

FIG. 1A to FIG. 1H are schematic cross-sectional views of a manufacturing process of a display device according to an embodiment of the disclosure.

FIG. 2 and FIG. 6 are respective schematic bottom views of a display device according to several embodiments of the disclosure.

FIG. 3 to FIG. 5, FIG. 7, FIG. 9, FIG. 10, and FIG. 12 are respective schematic cross-sectional view of a display device according to several embodiments of the disclosure.

FIG. 8 and FIG. 11 are respective schematic top views of a display device according to several embodiments of the disclosure.

### DETAILED DESCRIPTION OF DISCLOSED EMBODIMENTS

In the following embodiments, wordings used to indicate directions, such as “up,” “down,” “front,” “back,” “left,” and “right,” merely refer to directions in the accompanying drawings. Therefore, the directional wordings are used to illustrate rather than limit the disclosure.

In the accompanying drawings, the drawings illustrate the general features of the methods, structures, and/or materials used in the particular exemplary embodiments. However, the drawings shall not be interpreted as defining or limiting the scope or nature covered by the exemplary embodiments. For example, the relative size, thickness, and location of film layers, regions, and/or structures may be reduced or enlarged for clarity.

In the embodiments, the same or similar elements will be designated by the same or similar reference numerals, and descriptions thereof will be omitted. In addition, the features of different exemplary embodiments may be combined with each other when they are not in conflict, and simple equivalent changes and modifications made according to the specification or the claims are still within the scope of the disclosure.

The terminologies such as “first” and “second” mentioned in the specification or the claims are only used to name different elements or to distinguish different embodiments or scopes and are not intended to limit the upper or lower limit of the number of the elements, nor are they intended to limit the manufacturing order or disposition order of the elements. Furthermore, the disposition of an element/film layer on (or over) another element/film layer may include the situation where additional elements/film layers exist or do not exist between the two elements/film layers. In other words, the element/film layer may be disposed directly or indirectly on (or over) the other element/film layer. Moreover, the situation where the element/film layer is directly disposed on (or over) the other element/film layer represents that the two elements/film layers are in contact with each other, and no additional elements/film layers exist between the two elements/film layers.

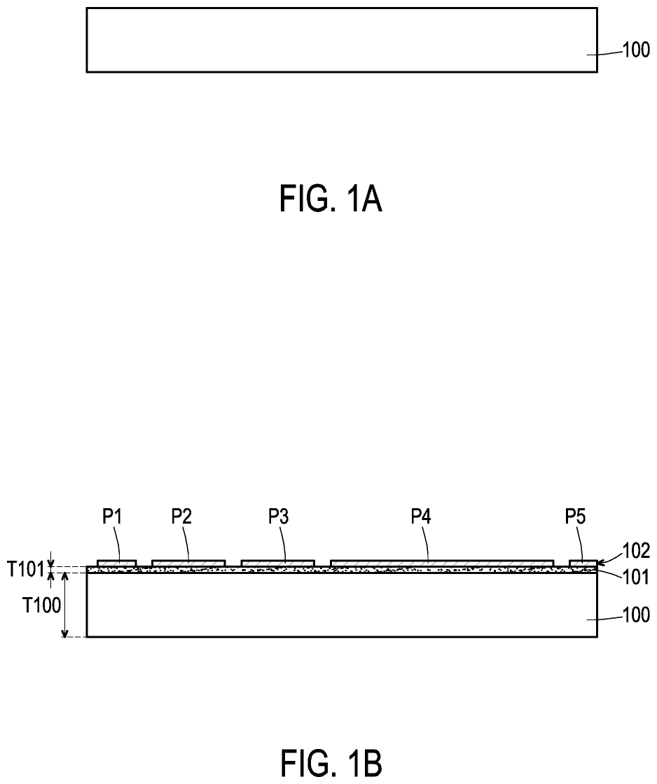

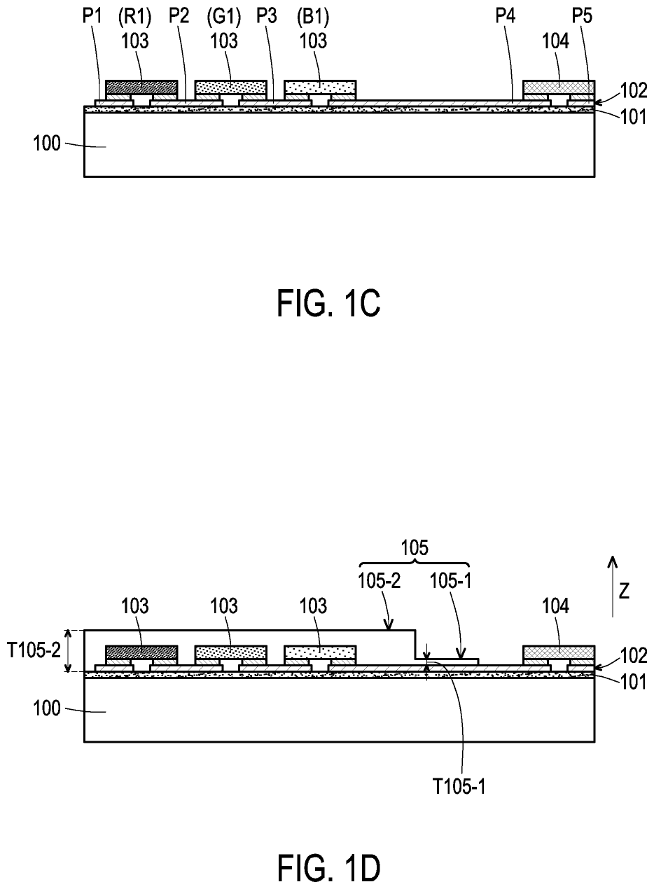

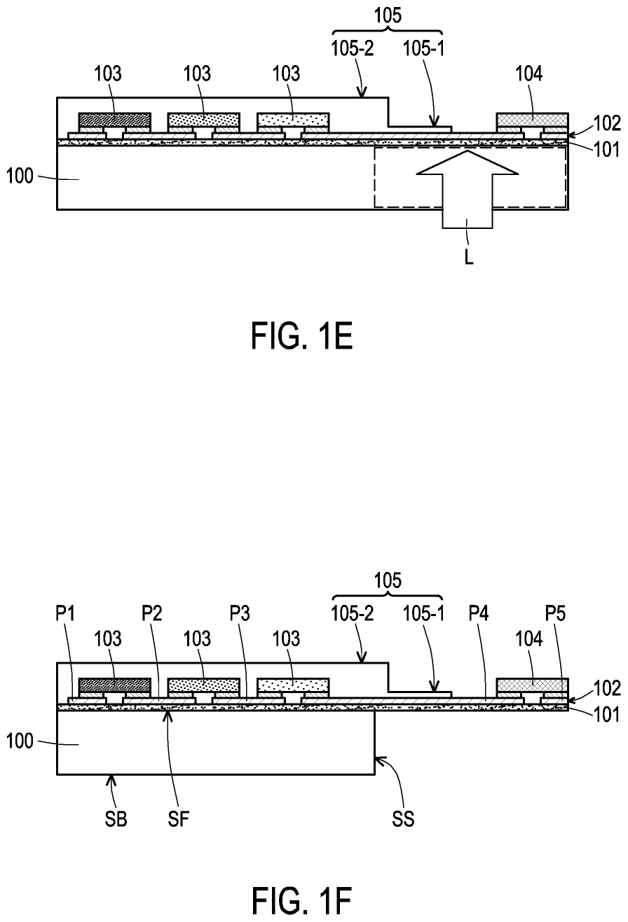

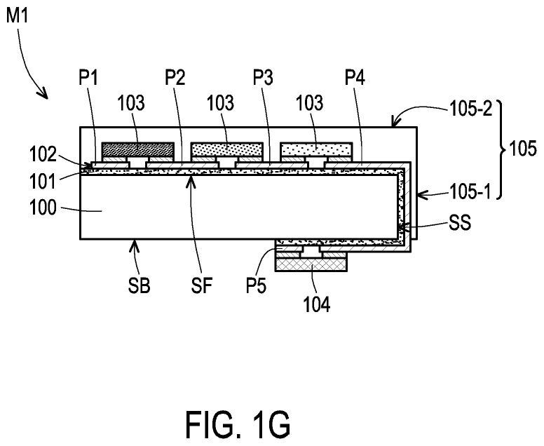

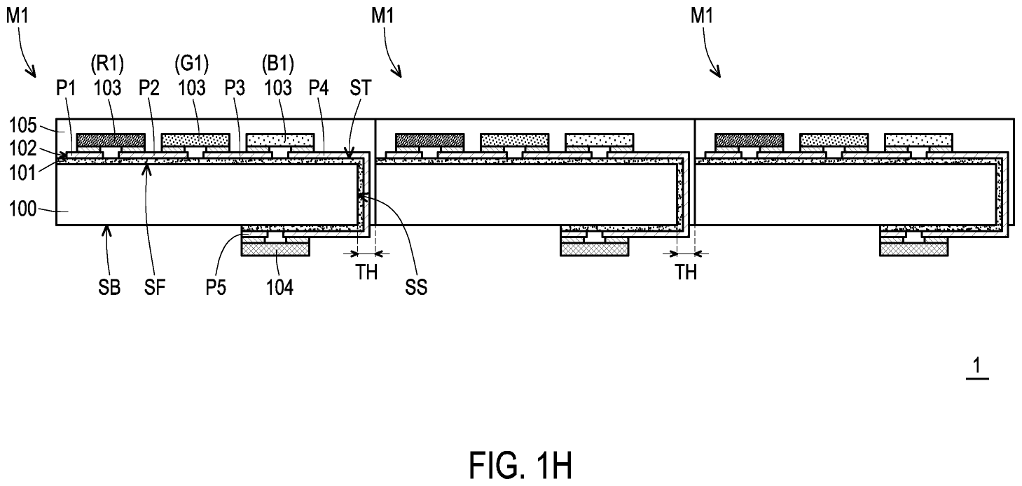

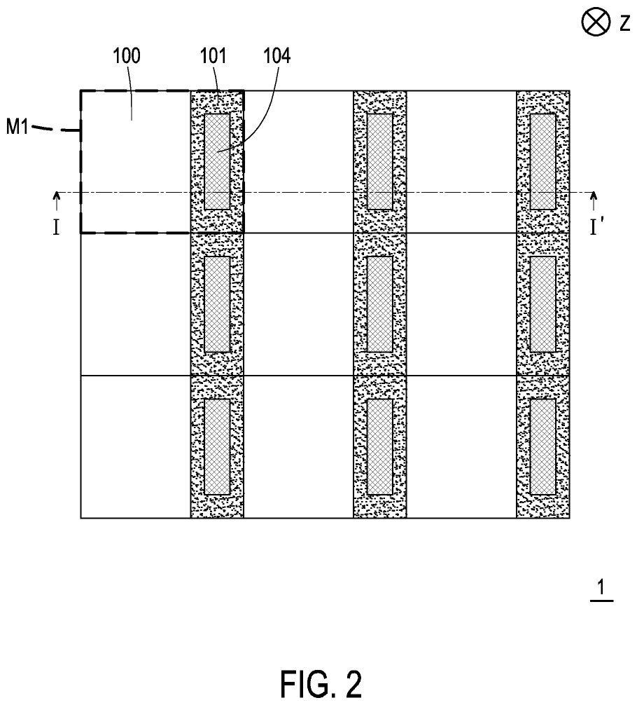

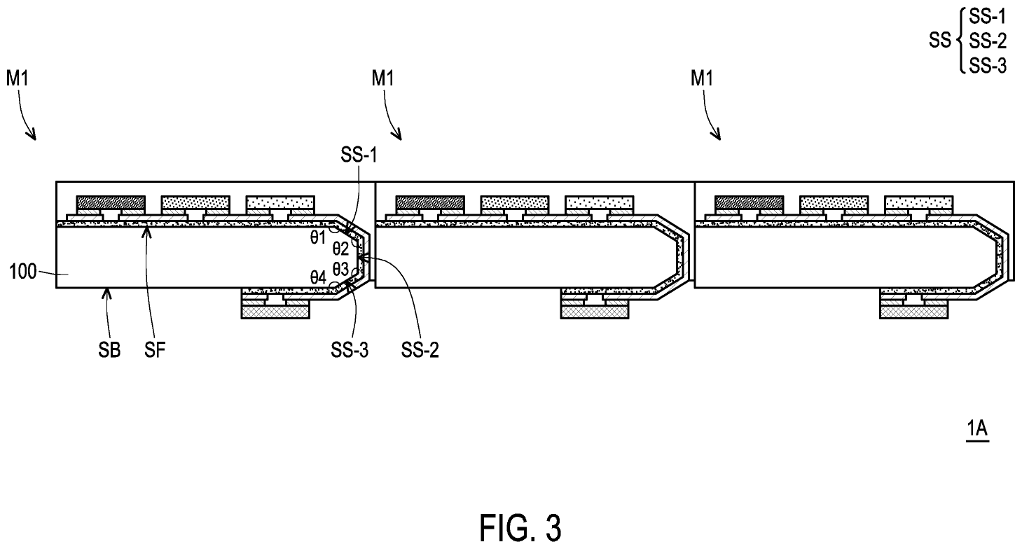

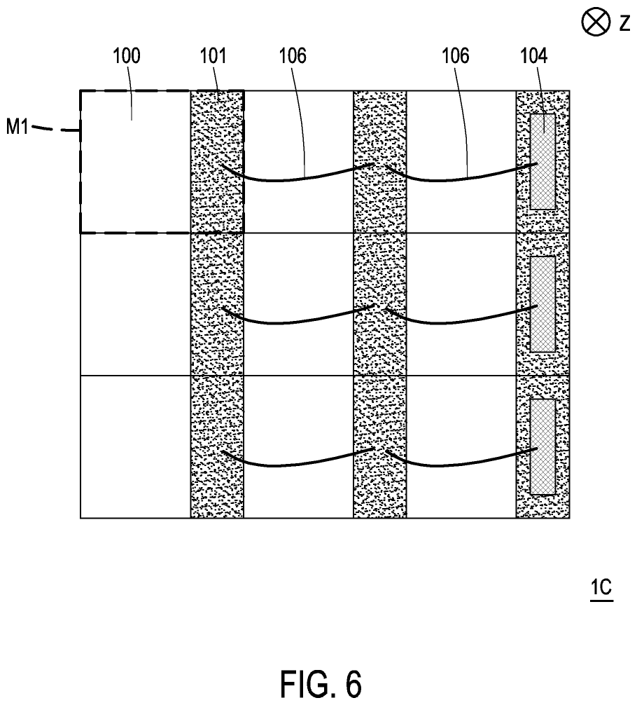

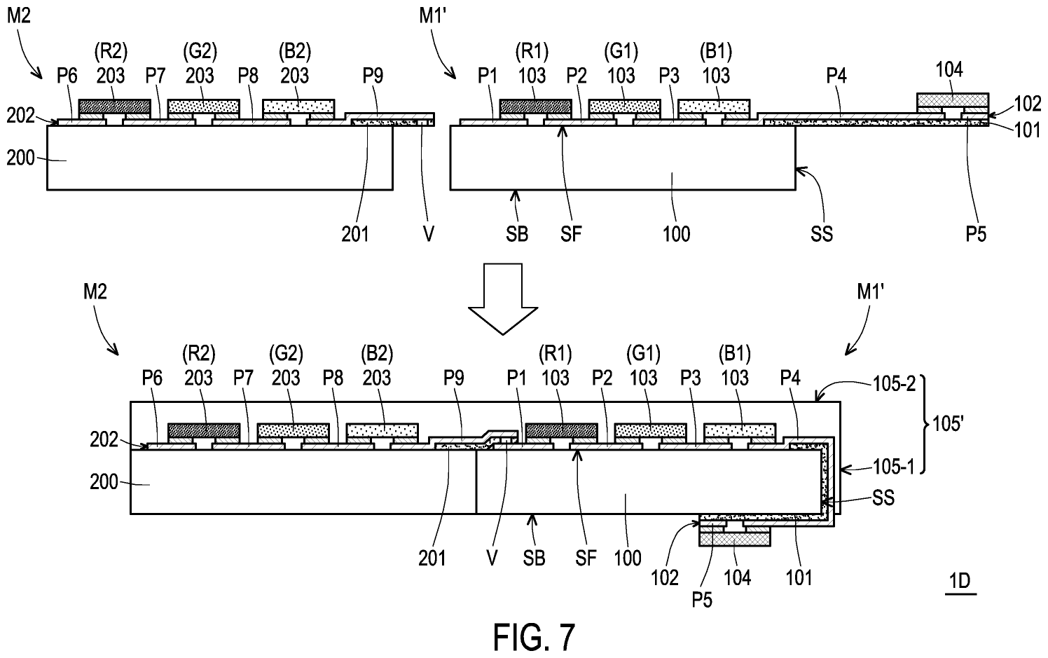

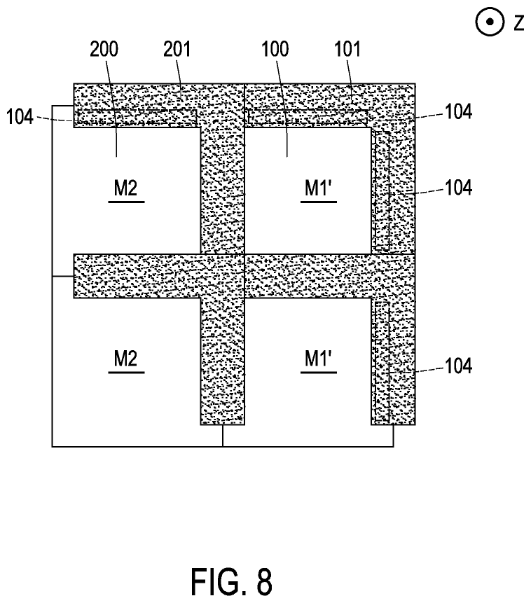

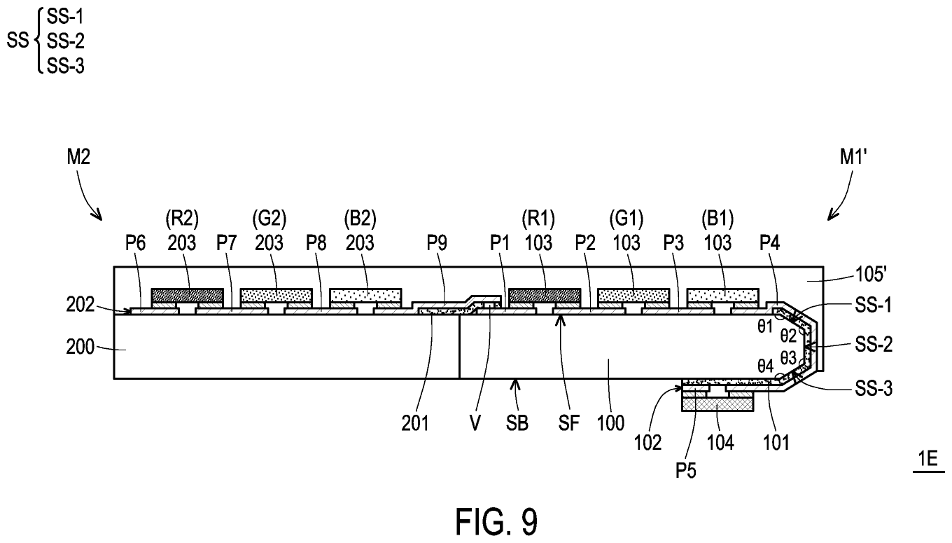

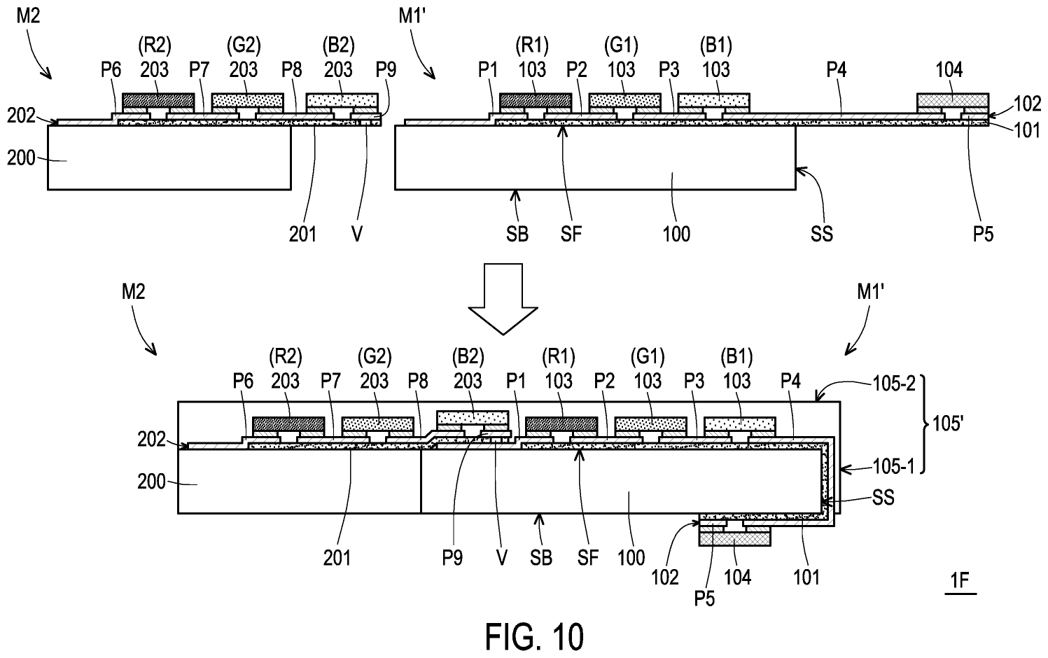

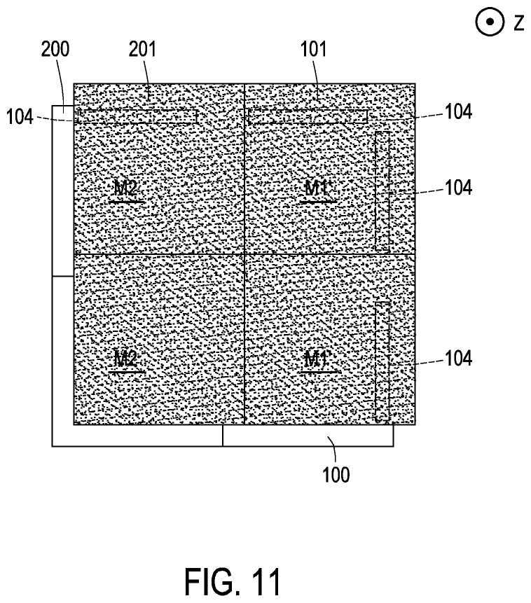

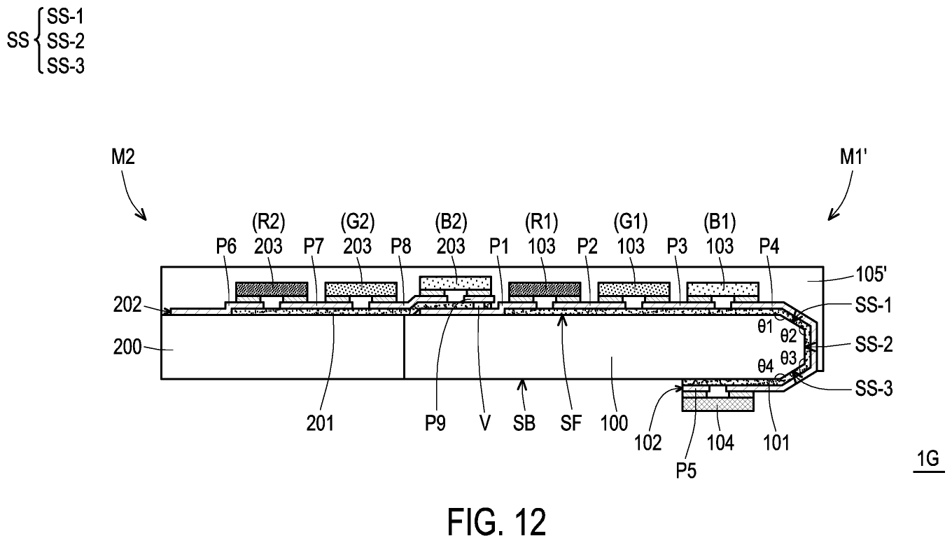

FIG. 1A to FIG. 1H are schematic cross-sectional views of a manufacturing process of a display device according to an embodiment of the disclosure. FIG. 2 and FIG. 6 are respective schematic bottom views of a display device according to several embodiments of the disclosure. FIG. 3 to FIG. 5, FIG. 7, FIG. 9, FIG. 10, and FIG. 12 are respective schematic cross-sectional view of a display device according to several embodiments of the disclosure. FIG. 8 and FIG. 11 are respective schematic top views of a display device according to several embodiments of the disclosure. In FIG. 2, FIG. 6, FIG. 8, and FIG. 11, elements and/or film layers other than a support substrate, a flexible substrate, and a driving element are omitted, so as to clearly illustrate the relationship of how the support substrate, the flexible substrate, and the driving element are relatively disposed.

With reference to FIG. 1A, a manufacturing method of a display device may include providing a first support substrate 100. The first support substrate 100 is a rigid substrate to hold or support film layers and/or elements subsequently formed on the first support substrate 100. For instance, a material of the first support substrate 100 includes glass, quartz, a ceramic material, sapphire or polyethylene terephthalate (PET), which should however not be construed as a limitation in this disclosure.

With reference to FIG. 1B, the manufacturing method of the display device may further include forming a first flexible substrate 101 on the first support substrate 100. A hardness of the first flexible substrate 101 is less than a hardness of the first support substrate 100. In another embodiment, a thickness T101 of the first flexible substrate 101 is less than or equal to a thickness T100 of the first support substrate 100, which should however not be construed as a limitation in the disclosure. The first flexible substrate 101 is, for instance, a substrate with flexibility, so as to be easily bent or curved. For instance, the first flexible substrate 101 may be formed on the first support substrate 100 through coating or adhesion, and a material of first flexible substrate 101 may include plastics, such as polycarbonate (PC), polyimide (PI), polypropylene (PP), or other appropriate flexible materials, which should however not be construed as a limitation in this disclosure.

The manufacturing method of the display device may further include forming a first conductive circuit 102 on the first flexible substrate 101. For instance, a conductive layer may be formed on the first flexible substrate 101 through coating, deposition, or transfer printing, and then the conductive layer is patterned on through photolithography and etching or the like, so as to form the first conductive circuit 102. The conductive layer may be a single-layer conductive layer; alternatively, the conductive layer may be a stacked layer of a plurality of conductive layers. In addition, a material of the conductive layer may include a transparent conductive material, an opaque conductive material, or a combination thereof. The transparent conductive material may include metal oxide, graphene, other appropriate transparent conductive materials, or a combination thereof. The metal oxide may include indium tin oxide, indium zinc oxide, aluminum tin oxide, aluminum zinc oxide, indium germanium zinc oxide, or other metal oxides. The opaque conductive material may include metal, alloy, or a combination thereof. In other embodiments, the first conductive circuit 102 may also be formed on the first support substrate 100, which will be elaborated hereinafter.

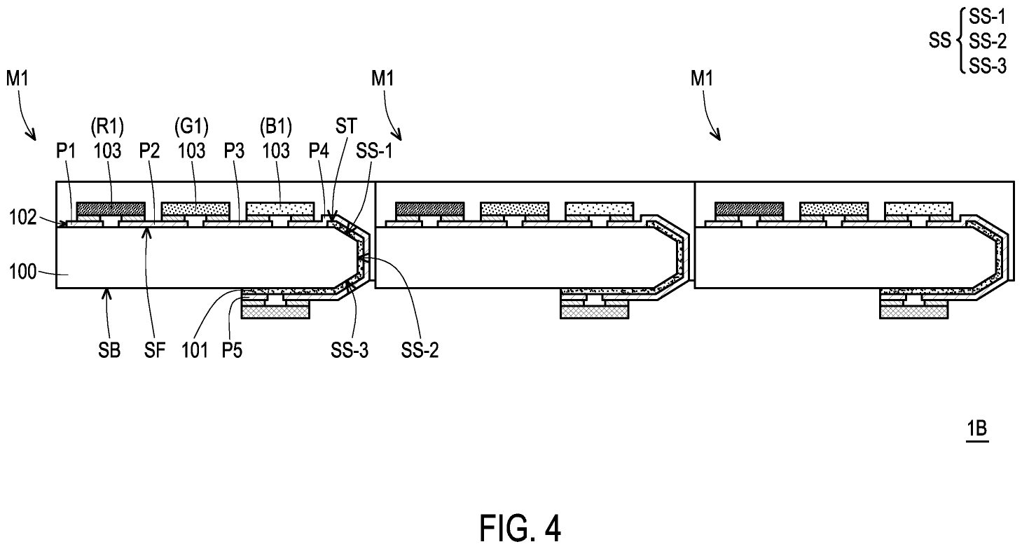

The first conductive circuit 102 may include a plurality of conductive patterns, such as a conductive pattern P1, a conductive pattern P2, a conductive pattern P3, a conductive pattern P4, and a conductive pattern P5, which should however not be construed as a limitation in this disclosure. In some embodiments, as shown in FIG. 1B, the first flexible substrate 101 fully covers the first support substrate 100, so that the first conductive circuit 102 formed after the first flexible substrate 101 is not in direct contact with the first support substrate 100. In other embodiments, although not shown in FIG. 1B (but in FIG. 4), the first flexible substrate 101 partially covers the first support substrate 100, one portion of the first conductive circuit 102 (such as the conductive pattern P1, the conductive pattern P2, the conductive pattern P3, and one portion of the conductive pattern P4) is directly disposed on the first support substrate 100 and is in direct contact with the first support substrate 100, and the other portion of the first conductive circuit 102 (such as the conductive pattern P5 and the other portion of the conductive pattern P4) is directly disposed on the first flexible substrate 101 without being in direct contact with the first support substrate 100.

With reference to FIG. 1C, the manufacturing method of the display device may further include placing a plurality of first electronic elements 103 on the first conductive circuit 102. In some embodiments, as shown in FIG. 1C, the first conductive circuit 102 located between the first electronic elements 103 and the first support substrate 100 is disposed on the first flexible substrate 101, which should however not be construed as a limitation in this disclosure. In other embodiments, although not in FIG. 1C (but in FIG. 4), the first conductive circuit 102 located between the first electronic elements 103 and the first support substrate 100 may be directly disposed on the first support substrate 100.

The first electronic elements 103 are electrically connected to the first conductive circuit 102, and the first electronic elements 103 may be connected to each other through the first conductive circuit 102; for instance, the first electronic elements 103 may be serially connected, connected in parallel, or connected in both manner through the first conductive circuit 102, which should however not be construed as a limitation in this disclosure. Although only the serial connection is shown in the accompanying drawings, it should be understood that the connections among the first electronic elements 103 may be changed according to requirements and should not be limited to what is shown in the accompanying drawings. The connections among the electronic elements in the following embodiment may be serial connections, parallel connections, or a combination thereof, which will not be repeated hereinafter.

The first electronic elements 103 may include a plurality of active elements, a plurality of passive elements, or a combination of the above. The active elements may include a plurality of light emitting diodes (LED), a plurality of photodiodes, a plurality of transistors, or a combination thereof, which should however not be construed as a limitation in this disclosure. The passive elements may include a plurality of capacitors, a plurality of resistors, a plurality of inductors, or a combination thereof, which should however not be construed as a limitation in this disclosure.

In some embodiments, as shown in FIG. 1C, the first electronic elements 103 may be a plurality of micro LEDs, e.g., a plurality of red micro LEDs R1 (only one is schematically shown), a plurality of green micro LEDs G1 (only one is schematically drawn), and a plurality of blue micro LEDs B1 (only one is schematically shown), which should however not be construed as a limitation in this disclosure. In addition, the micro LEDs are disposed on the first conductive circuit 102 through a mass transfer process and connected to each other through the first conductive circuit 102, which should however not be construed as a limitation in this disclosure. In FIG. 1C, the red micro LED R1 and the adjacent green micro LED G1 are serially connected through the conductive pattern P2, and the green micro LED G1 and the adjacent blue micro LED B1 are serially connected through the conductive pattern P3. However, the types of colors of the micro LEDs, the manner of arrangement of the micro LEDs, and the manner of connecting the micro LEDs and the conductive patterns may be changed according to different requirements and thus should not be limited to what is illustrated in FIG. 1C.

The manufacturing method of the display device may further include placing a driving element 104 on the first conductive circuit 102. The driving element 104 is electrically connected to the first conductive circuit 102, and the driving element 104 may be electrically connected to the first electronic elements 103 through the first conductive circuit 102. For instance, the driving element 104 may be a driving chip, and the driving element 104 may be bonded to the first conductive circuit 102 through a surface mount technology (SMT), which should however not be construed as a limitation in this disclosure. In FIG. 1C, the driving element 104 and the adjacent blue micro-LED B1 are serially connected through the conductive pattern P4, which should however not be construed as a limitation in this disclosure.

The order of placing the first electronic elements 103 and the driving element 104 on the first conductive circuit 102 is not limited. In some embodiments, the first electronic elements 103 may be disposed on the first conductive circuit 102 before the driving element 104 is disposed on the first conductive circuit 102. In another embodiment, the driving element 104 may be disposed on the first conductive circuit 102 before the first electronic elements 103 are disposed on the first conductive circuit 102.

With reference to FIG. 1D, the manufacturing method of the display device may further include forming a protection layer 105. The protection layer 105 covers the first electronic elements 103 and the first conductive circuit 102, so as to protect the first electronic elements 103 and the first conductive circuit 102 from, for instance, water, oxygen, scratches, and so on. In some embodiments, at least one portion of the first conductive circuit 102 is covered by the protection layer 105; for instance, the protection layer 105 may at least cover the first conductive circuit 102 connected to the first electronic elements 103, which should however not be construed as a limitation in this disclosure. For instance, the protection layer 105 may be formed on the first electronic elements 103 and the first conductive circuit 102 by molding, and a material of the protection layer 105 may include silicone, epoxy resin, PI, or other dielectric and light-transmitting materials, which should however not be construed as a limitation in this disclosure.

In some embodiments, the thickness of a portion of the protection layer 105 adjacent to the driving element 104 may be reduced, so as to reduce the splicing thickness. As shown in FIG. 1D, the protection layer 105 may have a first portion 105-1 and a second portion 105-2, where the first portion 105-1 is located between the driving element 104 and the second portion 105-2 and is located between the driving element 104 and the first electronic elements 103.

For instance, the second portion 105-2 may cover the first electronic elements 103 and a portion of the first conductive circuit 102 (e.g., covering the conductive pattern P1, the conductive pattern P2, the conductive pattern P3, and a portion of the conductive pattern P4); the first portion 105-1 is connected to the second portion 105-2 and extends from the second portion 105-2 towards the driving element 104, and the first portion 105-1 may cover a portion of the first conductive circuit 102 (e.g., covering a portion of the conductive pattern P4) and expose the driving element 104. According to different embodiments, the driving element 104 may also be covered by the first portion 105-1, where the first portion 105-1 covering the driving element 104 is thicker than the first portion 105-1 covering the first conductive circuit 102 located between the driving element 104 and the second portion 105-2, or the first portion 105-1 may have one single thickness. Alternatively, after the step shown in FIG. 1G, another protection layer not shown in the drawings may be further applied to cover the driving element 104 to protect the driving element 104 from, for instance, water, oxygen, scratches, and so on.

A thickness T105-1 of the first portion 105-1 may be less than a thickness T105-2 of the second portion 105-2, so as to reduce the splicing thickness (which will be described later). The thickness T105-1 of the first portion 105-1 refers to the maximum thickness of the first portion 105-1 in a direction (e.g., a direction Z) perpendicular to a carrying surface of the first support substrate 100 in a cross-sectional view of the display device. Similarly, the thickness T105-2 of the second portion 105-2 refers to the maximum thickness of the second portion 105-2 in the direction (e.g., the direction Z) perpendicular to the carrying surface of the first support substrate 100 in the cross-sectional view of the display device. In another embodiment, although not shown, the protection layer 105 may have one single thickness, i.e., the thickness T105-1=the thickness T105-2.

With reference to FIG. 1E, the manufacturing method of the display device may further include removing a portion of the first support substrate 100; for instance, the first support substrate 100 located below the first portion 105-1 and the driving element 104 is removed. For instance, the first support substrate 100 located below the first portion 105-1 and the driving element 104 may be irradiated by a laser beam L (as shown by a dashed-line box in FIG. 1E), so as to expose a lower surface of the first flexible substrate 101, which should however not be construed as a limitation in this disclosure.

With reference to FIG. 1F, in the above removal step, a side surface SS of the first support substrate 100 is formed, and the side surface SS is connected between a front surface SF of the first support substrate 100 and a back surface SB of the first support substrate 100.

With reference to FIG. 1G, the manufacturing method of the display device may further include bending the first flexible substrate 101 and the first conductive circuit 102 from the side surface SS of the first support substrate 100 to the back surface SB of the first support substrate 100 to form a first display module M1.

Through the bending step, the driving element 104 may be bent to the back surface SB of the first support substrate 100 together with the first flexible substrate 101 and the first conductive circuit 102, where the protection layer 105 exposes the first conductive circuit 102 bent to the back surface SB (e.g., the conductive pattern P5 and a portion of the conductive pattern P4), and the driving element 104 is disposed on the first conductive circuit 102 exposed by the protection layer 105.

The first portion 105-1 of the protection layer 105 covers the side surface SS of the first support substrate 100, and the second portion 105-2 of the protection layer 105 covers the front surface SF of the first support substrate 100. Through the aforesaid design of the first portion 105-1 of the protection layer 105 with the reduced thickness, the thickness of the film layer on the side surface SS of the first support substrate 100 may be reduced; thereby, when a plurality of first display modules M1 are spliced together, the splicing thickness TH may be reduced, as shown in FIG. 1H. In some embodiments, as mentioned above, in the event that the driving element 104 is not covered by the first portion 105-1, after the bending step, another protection layer not shown in the drawings may be selectively applied to cover the driving element 104, so as to protect the driving element 104 from, for instance, water, oxygen, scratches, and so on, which should however not be construed as a limitation in this disclosure.

Due to the design of bending the first flexible substrate 101 and the first conductive circuit 102 to the back surface SB of the first support substrate 100, it is neither necessary to form any additional circuit on the back surface SB of the first support substrate 100 nor necessary to form any conductive vias in the first support substrate 100, thereby simplifying the manufacturing process, reducing the manufacturing costs, and/or increasing the structural strength. In addition, the first display modules M1 may achieve size-free splicing, so as to meet the requirements for large sizes, curved surfaces, and/or special-shaped displays. Since each first display module M1 is equipped with an independent driving element 104, each first display module M1 may be driven independently, which is convenient for repairing and replacing the module.

With reference to FIG. 1H and FIG. 2, the display device 1 may include the first display modules M1. FIG. 2 schematically shows the display device 1 formed by splicing nine first display modules M1, where the cross-section of a sectional line I-I′ in FIG. 2 may refer to FIG. 1H. It should be understood that the number of the first display modules M1 and the manner of splicing the first display modules M1 in the display device 1 may be changed according to actual requirements. For instance, the number of the first display modules M1 in the display device 1 may be more in response to the requirement for large sizes. In addition, the first display modules M1 may be spliced in different ways to meet the needs of the special-shaped displays. Certainly, according to different requirements, the number of the first display module M1 in the display device 1 may also be one.

The first display module M1 includes the first support substrate 100, the first flexible substrate 101, the first conductive circuit 102, the first electronic elements 103, and the protection layer 105. The first flexible substrate 101 is disposed on the first support substrate 100. The first conductive circuit 102 is disposed on the first flexible substrate 101. The first electronic elements 103 are disposed on the first conductive circuit 102, where the first conductive circuit 102 is located between the first electronic elements 103 and the first support substrate 100 and is electrically connected to the first electronic elements 103. The protection layer 105 covers the first electronic elements 103 and the first conductive circuit 102. The first flexible substrate 101 and the first conductive circuit 102 are bent from the side surface SS of the first support substrate 100 to the back surface SB of the first support substrate 100.

In some embodiments, the first conductive circuit 102 may include a plurality of conductive patterns (such as the conductive pattern P1, the conductive pattern P2, the conductive pattern P3, the conductive pattern P4, and the conductive pattern P5), and one of the conductive patterns (e.g., the conductive pattern P1, the conductive pattern P2, the conductive pattern P3, or the conductive pattern P4) is disposed on the first flexible substrate 101, continuously extends below one of the first electronic elements 103 from a top surface ST of the first flexible substrate 101, and is electrically connected to the first electronic elements 103.

For instance, the conductive pattern P1 extends below the red micro LED R1 and is electrically connected to the red micro LED R1; two ends of the conductive pattern P2 respectively extend below the red micro LED R1 and the green micro LED G1 and are electrically connected to the red micro LED R1 and the green micro LED G1; two ends of the conductive pattern P3 respectively extend below the green micro LED G1 and the blue micro LED B1 and are electrically connected to the green micro LED G1 and the blue micro LED B1; two ends of the conductive pattern P4 respectively extend below the blue micro LED B1 and the driving element 104 and are electrically connected to the blue micro LED B1 and the driving element 104. Through the above design, it is not necessary to additionally arrange a flexible circuit board (not shown) that is configured to electrically connect the conductive circuit and the driving element.

In some embodiments, the first conductive circuit 102 may be completely disposed on the first flexible substrate 101. For instance, the first flexible substrate 101 may be located between the first electronic elements 103 and the first support substrate 100, and the first conductive circuit 102 located between the first electronic elements 103 and the first support substrate 100 is disposed on the first flexible substrate 101 and is not in direct contact with the first support substrate 100, which should however not be construed as a limitation in this disclosure. In other embodiments, although not shown in FIG. 1H (but shown in FIG. 4), at least one portion of the first conductive circuit 102 may be directly disposed on the first support substrate 100; for instance, the first conductive circuit 102 located between the first electronic elements 103 and the first support substrate 100 may be directly disposed on the first support substrate 100 and in direct contact with the first support substrate 100.

In the above exemplary embodiment, although the driving element 104 is disposed on the back surface SB of the first support substrate 100, it should be understood that the driving element 104 is not limited to be disposed on the back surface SB of the first support substrate 100. In some embodiments, although not shown, the driving element 104 may be disposed on the front surface SF of the first support substrate 100. Said changes are applicable in the following embodiments and thus will not be further described below.

With reference to FIG. 3, the main differences between a display device 1A and the display device 1 in FIG. 1H are described below. In the display device 1A, the side surface SS of the first support substrate 100 has a chamfer to reduce the bending degree of circuits, which is conducive to reducing the probability of disconnections or improving reliability. For instance, the side surface SS may be a curved surface formed by laser cutting and may include a sub-surface SS-1, a sub-surface SS-2, and a sub-surface SS-3, where the sub-surface SS-1 is connected between the front surface SF and the sub-surface SS-2, the sub-surface SS-2 is connected between the sub-surface SS-1 and the sub-surface SS-3, and the sub-surface SS-3 is connected between the sub-surface SS-2 and the back surface SB. A chamfer θ1 is formed between the front surface SF and the subsurface SS-1. A chamfer θ2 is formed between the sub-surface SS-1 and the sub-surface SS-2. A chamfer θ3 is formed between the sub-surface SS-2 and the sub-surface SS-3. A chamfer θ4 is formed between the sub-surface SS-3 and the back surface SB. In some embodiments, the chamfer θ1, the chamfer θ2, the chamfer, and the chamfer θ4 may fall within a range from 130 degrees to 160 degrees, respectively; that is, 130°≤θ1≤160°, 130°≤θ2≤160°, 130°≤θ3≤160°, and 130°≤θ4≤160°. However, the degree or the number of the chamfers may be changed according to actual requirements and thus should not be construed as limitation in the disclosure.

With reference to FIG. 4, the main differences between a display device 1B and the display device 1A in FIG. 3 are described below. In the display device 1B, the first flexible substrate 101 is not located between the first electronic elements 103 and the first support substrate 100. For instance, the first flexible substrate 101 may extend from the front surface SF adjacent to the side surface SS to the back surface SB along the sub-surface SS-1, the sub-surface SS-2, and the sub-surface SS-3, and the conductive pattern P4 continuously extends below one of the first electronic elements 103 (e.g., the blue micro LED B1) from the top surface ST of the first flexible substrate 101 and is electrically connected to the first electronic elements 103. The first conductive circuit 102 (e.g., the conductive pattern P1, the conductive pattern P2, and the conductive pattern P3) located between the first electronic elements 103 and the first support substrate 100 is, for instance, directly disposed on the first support substrate 100 and is in direct contact with the first support substrate 10.

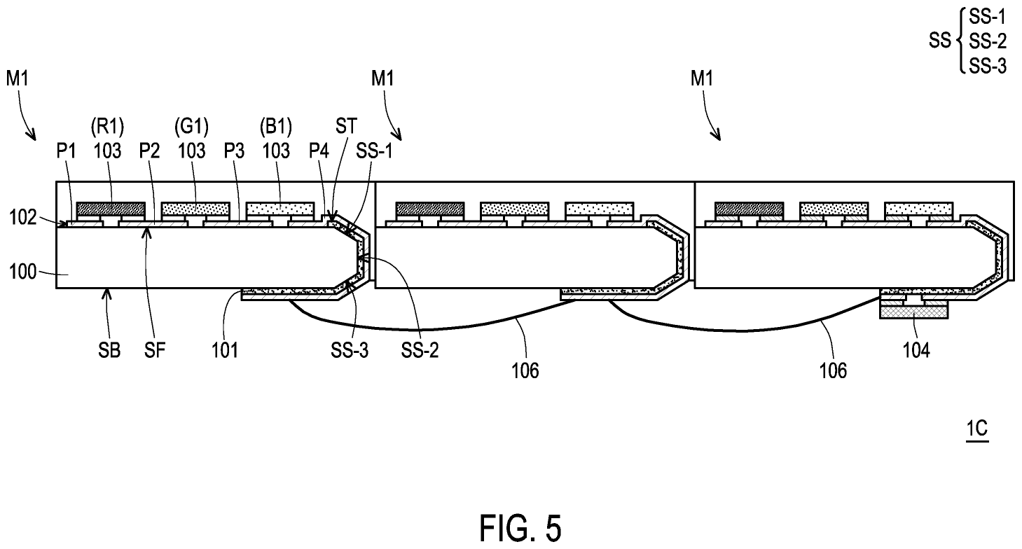

With reference to FIG. 5 and FIG. 6, the main differences between a display device 1C and the display device 1B in FIG. 4 are described below. In the display device 1C, the number of the driving elements 104 is less than the number of the first display modules M1, where the back surfaces of some of the first display modules M1 are equipped with the driving elements 104, while the back surfaces of the other first display modules M1 are not equipped with the driving elements 104. The display device 1C further includes connection members 106, and the connection members 106 are connected between a plurality of first conductive circuits 102 exposed by a plurality of protection layers 105 (i.e., the first conductive circuits 102 located on the back surfaces SB of the first support substrates 100). For instance, the connection members 106 may include conductive wires, flexible printed circuit boards, or other elements that may be configured for electrical connection.

The first display modules M1 are electrically connected through the connection members 106, and the first display modules M1 may share the driving elements 104, thereby reducing the number of the driving elements 104. Besides, it is relatively easy to repair and replace the first display modules M1.

With reference to FIG. 7 and FIG. 8, a display device 1D may be a transparent display device or a non-transparent display device. The main differences between the display device 1D and the display device 1B in FIG. 4 are described below. In the display device 1D, a first display module M1′ and a second display module M2 are spliced. The manufacturing method of the first display module M1′ may be referred to as the steps shown in FIG. 1A to FIG. 1F and thus will not be described again.

The second display module M2 may include a second support substrate 200, a second flexible substrate 201, a second conductive circuit 202, and a plurality of second electronic elements 203, which should however not be construed as a limitation in this disclosure. Although not shown in FIG. 7 or FIG. 8, the second display module M2 may further include other elements or film layers according to different requirements.

The details of the second support substrate 200 and the second flexible substrate 201 (e.g., the material, the thickness, the hardness, and/or the relationship of how the second support substrate 200 and the second flexible substrate 201 are relatively disposed) may be referred to as the relevant descriptions of the first support substrate 100 and the first flexible substrate 101 and thus will not be described again.

The main difference between the second flexible substrate 201 and the first flexible substrate 101 lies in that the second flexible substrate 201 has a conductive through hole V. The conductive through hole V penetrates the second flexible substrate 201 and is attached to the first conductive circuit 102 (e.g., the conductive pattern P1) after the first display module M1′ and the second display module M2 are spliced. A manufacturing method of the conductive through hole V may include forming a through hole (not shown) in the second flexible substrate 201 and filling the through hole with a conductive material. A method of forming the through hole may include laser drilling, which should however not be construed as a limitation in this disclosure. The conductive material may include tin, and a method of filling the through hole with the conductive material may include tin brushing or tin spraying, which should however not be construed as a limitation in this disclosure. In addition, the method of attaching the conductive through hole V to the first conductive circuit 102 may include but may not be limited to a reflow process.

The second conductive circuit 202 is disposed on the second flexible substrate 201 and electrically connected to the first conductive circuit 102 through the conductive through hole V. A material and a manufacturing method of the second conductive circuit 202 may be referred to as the relevant descriptions of the first conductive circuit 102 and thus will not be further described.

The second conductive circuit 202 may include a plurality of conductive patterns, such as a conductive pattern P6, a conductive pattern P7, a conductive pattern P8, and a conductive pattern P9, which should however not be construed as a limitation in this disclosure. In some embodiments, as shown in FIG. 7, the second flexible substrate 201 partially covers the second support substrate 200, some portions of the second conductive circuit 202 (e.g., the conductive pattern P6, the conductive pattern P7, the conductive pattern P8, and one portion of the conductive pattern P9) are directly disposed on the second support substrate 200 and is in direct contact with the second support substrate 200, and the other portions of the second conductive circuit 202 (e.g., the other portion of the conductive pattern P9) are directly disposed on the second flexible substrate 201 and are not in direct contact with the second support substrate 200. In other embodiments, although not shown in FIG. 7 (but shown in FIG. 10), the second flexible substrate 201 may extend between the second electronic elements 203 and the second support substrate 200.

The second electronic elements 203 are disposed on the second conductive circuit 202, where the second conductive circuit 202 is located between the second electronic elements 203 and the second support substrate 200 and is electrically connected to the second electronic elements 203, and the second electronic elements 203 may be electrically connected to each other through the second conductive circuit 202.

The second electronic elements 203 may include a plurality of active elements, a plurality of passive elements, or a combination thereof. In some embodiments, as shown in FIG. 7, the second electronic elements 203 may be a plurality of micro LEDs, e.g., a plurality of red micro LEDs R2 (only one is schematically shown), a plurality of green micro LEDs G2 (only one is schematically drawn), and a plurality of blue micro LEDs B2 (only one is schematically shown), which should however not be construed as a limitation in this disclosure. In addition, the micro LEDs are disposed on the second conductive circuit 202 through a mass transfer process and connected to each other through the second conductive circuit 202, which should however not be construed as a limitation in this disclosure. In FIG. 7, the red micro LED R2 and the adjacent green micro LED G2 are serially connected through the conductive pattern P7, and the green micro LED G2 and the adjacent blue micro LED B2 are serially connected through the conductive pattern P8. In addition, the blue micro-LED B2 and the red micro-LED R1 in the first display module M1′ are serially connected through the conductive pattern P9, the conductive through hole V, and the conductive pattern P1. However, the types of colors of the micro LEDs, the manner of arrangement of the micro LEDs, and the manner of connecting the micro LEDs and the conductive patterns may be changed according to different requirements and thus should not be limited to what is illustrated in FIG. 7.

A protection layer 105′ is formed after the first display module M1′ and the second display module M2 are spliced, and the protection layer 105′ not only covers the first electronic elements 103 and the first conductive circuit 102 but also covers the second electronic elements 203 and the second conductive circuit 202. In some embodiments, a thickness of a portion of the protection layer 105′ adjacent to the driving element 104 may be reduced (e.g., the thickness of the first portion 105-1 covering the side surface SS of the first support substrate 100 may be less than the thickness of the second portion 105-2 covering the front surface SF of the first support substrate 100), so as to reduce the splicing thickness or the thickness of border frames. According to different embodiments, before the splicing step, a first protection layer (not shown) covering the first electronic elements 103 and the first conductive circuit 102 and a second protection layer covering the second electronic elements 203 and the second conductive circuit 202 may be formed first, where the first protection layer exposes the splicing region (e.g., a region where the conductive pattern P1 is bonded to the second flexible substrate 201 and the conductive through hole V) and/or the driving element 104; after the splicing step, a third protection layer covering the splicing region and/or the driving element 104 may be selectively formed, which should however not be construed as a limitation in this disclosure.

According to different requirements, the left side of the second display module M2 may also be spliced with another second display module not shown in the drawings. The another second display module may have the same structure as that of the second display module M2 shown in FIG. 7, and in the another second display module the second flexible substrate protruding from the second support substrate and the second conductive circuit thereon may be attached to the conductive pattern P6 shown in FIG. 7 and may be serially connected to the second display module M2 shown in FIG. 7.

According to different requirements, the way to splice the second display module M2 with another second display module not shown in the drawings is not limited to splicing the left side of the second display module M2 to the another second display module as described above, and the second display module M2 may be spliced to the top or the bottom of the another second display module. As shown in FIG. 8, the top-bottom splicing manner of the two second display modules M2 is the same as the splicing manner described above. For instance, a plurality of (e.g., two) second display modules M2 arranged in a vertical direction as shown in FIG. 8 may share the driving element 104, and a plurality of (e.g., two) first display modules M1′ arranged in a vertical direction as shown in FIG. 8 may share the driving element 104. In FIG. 8, the driving element 104 is disposed on the top and on the right side. In other different embodiments, the driving element 104 in FIG. 8 may also be disposed on the top or on the right side. Besides, as shown by the first display module M1′ in the lower right corner, the splicing manner in different directions may be different, such as the first display modules M1′ spliced in a bending manner, the first display module M1′ and the second display module M2 spliced with each other through the conductive through hole, and so forth.

With reference to FIG. 9, the main differences between a display device 1E and the display device 1D in FIG. 7 are described below. In the display device 1E, the side surface SS of the first display module M1′ has the aforementioned chamfer design to reduce the bending degree of circuits, which is conducive to reducing the probability of disconnections or improving reliability.

With reference to FIG. 10, the main differences between a display device 1F and the display device 1D in FIG. 7 are described below. In the display device 1F, the second flexible substrate 201 is located between the second electronic elements 203 and the second support substrate 200. In addition, at least one of the second electronic elements 203 (e.g., the blue micro LED B2) is disposed on the second flexible substrate 201 protruding from the second support substrate 200. Thereby, after the first display module M1′ and the second display module M2 are spliced, the at least one of the second electronic elements 203 (e.g., the blue micro LED B2) and the first support substrate 100 are overlapped.

Due to the above design, a distance between two adjacent electronic elements in the first display module M1′ and the second display module M2 (e.g., the distance between the blue micro LED B2 and the red micro LED R1) may be reduced, so that seams caused by splicing may be less visible.

According to different requirements, another second display module not shown in the drawings may be spliced to the left side of the second display module M2, and the another second display module may have the same structure as that of the second display module shown in FIG. 10. Besides, in the another second display module, the second flexible substrate protruding from the second support substrate and the overlapping second conductive circuit may be attached to the conductive pattern P6 shown in FIG. 10 and serially connected to the second display module M2 shown in FIG. 10.

According to different requirements, the way to splice the second display module M2 with another second display module not shown in the drawings is not limited to splicing the left side of the second display module M2 to the another second display module as described above, and the second display module M2 may be spliced to the top or the bottom of the another second display module. As shown in FIG. 11, the top-bottom splicing manner of the two second display modules M2 is the same as the splicing manner described above. For instance, a plurality of (e.g., two) second display modules M2 arranged in a vertical direction as shown in FIG. 11 may share the driving element 104, and a plurality of (e.g., two) first display modules M1′ arranged in a vertical direction as shown in FIG. 11 may share the driving element 104. In FIG. 11, the driving element 104 is disposed on the top and on the right side. In other different embodiments, the driving element 104 in FIG. 11 may also be disposed on the top or on the right side. Besides, as shown by the first display module M1′ in the lower right corner, the splicing manner in different directions may be different, such as the first display modules M1′ spliced in a bending manner, the first display module M1′ and the second display module M2 spliced with each other through the conductive through hole, and so forth.

With reference to FIG. 12, the main differences between a display device 1G and the display device 1F in FIG. 10 are described below. In the display device 1G, the side surface SS of the first display module M1′ has the aforementioned chamfer design to reduce the bending degree of circuits, which is conducive to reducing the probability of disconnection or improving reliability.

To sum up, in one or more embodiments of the disclosure, due to the design of bending the first flexible substrate and the first conductive circuit to the back surface of the first support substrate, it is neither necessary to form any additional circuit on the back surface of the first support substrate nor necessary to form any conductive vias in the first support substrate. Thereby, the manufacturing steps may be simplified, the manufacturing costs may be reduced, and/or the structural strength may be enhanced. In addition, the first display module may be spliced with other display modules and achieve size-free splicing, so as to meet the requirements for large sizes, curved surfaces, and/or special-shaped displays. In some embodiments, the first display module may be equipped with the independent driving element or share the driving element with other modules, which is convenient for repairing and replacing the module. In some embodiments, the protection layer may be partially thinned down, so as to reduce the splicing thickness. In some embodiments, the side surface of the first support substrate may have the chamfer to reduce the bending degree of circuits, which is conducive to reducing the probability of disconnection or improving reliability. In some embodiments, the electronic elements may be disposed on the flexible substrate protruding from the support substrate and may be attached to the conductive circuit of another module to reduce the distance between two adjacent electronic elements in different modules, which is conducive to the reduction of the visibility of the seams caused by splicing.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A display device, comprising:
a first display module, comprising:
a first support substrate;
a first flexible substrate, disposed on the first support substrate;
a first conductive circuit, disposed on the first support substrate;
a plurality of first electronic elements, disposed on the first conductive circuit, wherein the first conductive circuit is located between the plurality of first electronic elements and the first support substrate and electrically connected to the plurality of first electronic elements; and
a protection layer, covering the plurality of first electronic elements and the first conductive circuit;
wherein the first flexible substrate and the first conductive circuit are bent from a side surface of the first support substrate to a back surface of the first support substrate.

2. The display device according to claim 1, wherein the first conductive circuit comprises a plurality of conductive patterns, and at least one of the plurality of conductive patterns is disposed on the first flexible substrate and continuously extends below one of the plurality of first electronic elements from a top surface of the first flexible substrate and electrically connected to the plurality of first electronic elements.

3. The display device according to claim 1, wherein the first conductive circuit located between the plurality of first electronic elements and the first support substrate is disposed on the first flexible substrate.

4. The display device according to claim 1, wherein the first conductive circuit located between the plurality of first electronic elements and the first support substrate is directly disposed on the first support substrate.

5. The display device according to claim 1, wherein the side surface of the first support substrate has a chamfer.

6. The display device according to claim 1, wherein the protection layer has a first portion covering the side surface of the first support substrate and a second portion covering a front surface of the first support substrate.

7. The display device according to claim 1, wherein a thickness of the first portion is less than or equal to a thickness of the second portion.

8. The display device according to claim 1, further comprising a plurality of the first display modules spliced to each other,
wherein in each of the plurality of first display modules, the protection layer exposes the first conductive circuit bent onto the back surface, and the display device further comprises:
a plurality of driving elements, respectively disposed on a plurality of the first conductive circuits exposed by a plurality of the protection layers.

9. The display device according to claim 8, further comprising:
another protection layer, covering the plurality of driving elements, respectively.

10. The display device according to claim 1, further comprising a plurality of the first display modules spliced to each other,
wherein in each of the plurality of first display modules, the protection layer exposes the first conductive circuit bent onto the back surface, and the display device further comprises:
a driving element, disposed on the first conductive circuit exposed by the protection layer; and
a connection member, connected to a plurality of the first conductive circuits exposed by a plurality of the protection layers.

11. The display device according to claim 1, further comprising:
a second display module, spliced to the first display module and comprising:
a second support substrate;
a second flexible substrate, disposed on the second support substrate and having a conductive through hole attached to the first conductive circuit;
a second conductive circuit, disposed on the second flexible substrate and electrically connected to the first conductive circuit through the conductive through hole;
a plurality of second electronic elements, disposed on the second conductive circuit, wherein the second conductive circuit is located between the plurality of second electronic elements and the second support substrate and electrically connected to the plurality of second electronic elements;
wherein the protection layer further covers the plurality of second electronic elements and the second conductive circuit.

12. The display device according to claim 11, wherein the second flexible substrate is located between the plurality of second electronic elements and the second support substrate, and at least one of the plurality of second electronic elements is overlapped with the first support substrate.

13. The display device according to claim 11, wherein the second conductive circuit located between the plurality of second electronic elements and the second support substrate is directly disposed on the second support substrate.

14. The display device according to claim 11, further comprising a plurality of the second display modules spliced with each other, wherein the second conductive circuit is disposed on the second flexible substrate and electrically connected to a second conductive circuit of another of the plurality of the second display modules through the conductive through hole.
